(19) United States
(12) Patent Application Publication
(10) Pub. No.: US 2012/0021127 A1
(43) Pub. Date: Jan. 26, 2012

(54) MATERIAL FOR CHEMICAL VAPOR DEPOSITION AND PROCESS FOR FORMING SILICON-CONTAINING THIN FILM USING SAME

(75) Inventors: Hiroki Sato, Tokyo (JP); Yoshihide Mizuo, Tokyo (JP); Akio Saito, Tokyo (JP); Junji Ueyama, Tokyo (JP)

(73) Assignee: ADEKA CORPORATION, Tokyo (JP)

(21) Appl. No.: 13/145,474

(22) PCT Filed: Feb. 15, 2010
(86) PCT No.: PCT/JP2010/052200

§ 371 Date: Jul. 20, 2011

(30) Foreign Application Priority Data
Mar. 19, 2009 (JP) 2009-068621

(51) Int. Cl. C23C 16/34; C07F 7/02; C23C 16/44

(52) U.S. Cl. 427/248.1; 556/410

(57) ABSTRACT

A material for chemical vapor deposition containing an organic silicon-containing compound represented by formula: HSiCl(NR¹R²)(NR³R⁴), wherein R¹ and R³ each represent C1-C4 alkyl or hydrogen; and R² and R⁴ each represent C1-C4 alkyl. The material is particularly suitable as a material for forming a silicon nitride thin film on a substrate by chemical vapor deposition. The use of the material allows for film formation at low temperatures ranging from 300° to 500° C.

### TECHNICAL FIELD

This invention relates to a material for chemical vapor deposition containing an organic silicon-containing compound having a specific structure and a process for fabricating a silicon-containing thin film by chemical vapor deposition using the material.

### BACKGROUND ART

A silicon-containing thin film is used as an electronic element of electronic components, such as capacitor films, gate films, barrier films, and gate insulators, and an optical element of optical communication devices, such as optical waveguides, optical switches, and optical amplifiers. With the recent increase in integration scale and density in electronic devices, these electronic elements and optical elements have shown tendency to be miniaturized. Under these circumstances, there has been a demand for a silicon-containing thin film to be still thinner. To meet the demand, conventional silicon oxide thin films have been replaced with silicon nitride thin films.

Processes for forming the above-described silicon-containing thin films include dipping-pyrolysis, sol-gel process, chemical vapor deposition (hereinafter abbreviated as CVD), and atomic layer deposition (hereinafter, ALD). Processes using a precursor in a vaporized state, such as CVD and ALD, are best suited because of many advantages, such as compositional controllability, excellent step coverage, suitability to large volume production, and capability of hybrid integration.

Inorganic chlorosilanes, such as dichlorosilane and hexachlorodisilane, have generally been used as a precursor in CVD or ALD. However, because the film formation processes using such a precursor need high temperatures of 700° to 900° C., they are unsuitable to the steps where a wafer is not allowed to be heated to such high temperatures, such as the steps after the fabrication of metal wiring. The high-temperature process also raises the problem that the impurities in a shallow diffusion layer is caused to diffuse deeper by the heat, making it difficult to achieve electronic element miniaturization.

To settle these problems, film formation techniques using a precursor derived from an inorganic chlorosilane by introducing an organic group have been studied as an approach to low-temperature film formation. For example, patent document 1 below discloses a technique for depositing an Si₃N₄ film by CVD using SiH₂(NH(C₄H₉))₂(bis-tert-butylaminosilane: BTBAS) as a precursor.

Patent document 2 below discloses a film formation process using SiCl(N(C₂H₅)₂)₃, SiCl(NH(C₂H₅))₃, SiH₂(N(C₃H₇)₂)₂, or Si(N(CH₃)₂)₄ as a precursor.

However, in the light of the film formation temperatures employed in the techniques of patent documents 1 and 2, which are not lower than 600° to 800° C., these techniques are not deemed to have achieved sufficient reduction in film formation temperature.

### CITATION LIST

### Patent Literature

Patent document 1: US 2006/121746A1

Patent document 2: CN 1834288A

### SUMMARY OF INVENTION

### Technical Problem

An object of the invention is to provide a material for chemical vapor deposition containing an organic silicon-containing compound that allows for film formation at low temperatures ranging from 300° to 500° C. and establishes a process achieving good reactivity.

### Solution to Problem

As a result of extensive investigations, the inventors have found that a chemical vapor deposition material containing an organic silicon-containing compound having a specific structure provides a solution to the above problem and thus reached the invention.

The invention provides a material for chemical vapor deposition containing an organic silicon-containing compound represented by formula:

HSiCl(NR¹R²)(NR³R⁴)

wherein R¹ and R³ each represent an alkyl group having 1 to 4 carbon atoms or hydrogen; and R² and R⁴ each represent an alkyl group having 1 to 4 carbon atoms.

The invention also provides a process for forming a silicon-containing thin film by chemical vapor deposition using the material for chemical vapor deposition.

### Advantageous Effects of Invention

The invention provides a material for chemical vapor deposition containing an organic silicon-containing compound that allows for film formation at low temperatures ranging from 300° to 500° C. and establishes a process achieving good reactivity.

### BRIEF DESCRIPTION OF DRAWINGS

FIG. 1 shows the FT-IR spectrum of compound No. 8 measured before and after introducing NH₃ gas at room temperature in Evaluation Example 2.

FIG. 2 shows the FT-IR spectrum of compound No. 8 measured before and after introducing NH₃ gas at 200° C. in Evaluation Example 2.

FIG. 3 shows the FT-IR spectrum of comparative compound No. 1 measured before and after introducing NH₃ gas at room temperature and 200° C. in Evaluation Example 2.

FIG. 4 shows the FT-IR spectrum of compound No. 8 measured after introducing NH₃ gas at room temperature and baking on an Si wafer at 700° C. in Evaluation Example 3.

FIG. 5 schematically illustrates an ALD apparatus used in a thin film formation process according to the invention.

### DESCRIPTION OF EMBODIMENTS

The chemical vapor deposition material of the invention contains, as a thin film precursor, an organic silicon-containing compound represented by general formula:

HSiCl(NR¹R²)(NR³R⁴)

wherein R¹ and R³ each represent an alkyl group having 1 to 4 carbon atoms or hydrogen; and R² and R⁴ each represent an alkyl group having 1 to 4 carbon atoms. The chemical vapor deposition material of the invention is useful in the formation of silicon-containing thin films, e.g., thin films of silicon oxide, silicon nitride, silicon carbonitride, or a complex oxide of silicon and other metal element(s). It is especially suitable as a chemical vapor deposition material achieving silicon nitride thin film formation at low temperatures. As used herein, the term “material for chemical vapor deposition” or “chemical vapor deposition material” is intended to mean both a CVD material and an ALD material unless specifically distinguished.

The organic silicon-containing compound is characterized by having silicon bonded to hydrogen, chlorine, and amino groups. The organic silicon-containing compound has improved reactivity and achieves an increased deposition rate owing to its chlorine atom. Having amino groups, the organic silicon-containing compound permits low temperature film deposition.

Examples of the alkyl group with 1 to 4 carbon atoms as represented by R¹ and R² in the above described general formula include methyl, ethyl, propyl, 2-propyl, butyl, 2-butyl, isobutyl, and tert-butyl. R¹ and R³ in the general formula may be the same or different. The same applies to R² and R⁴.

Examples of the organic silicon-containing compound represented by the general formula include compound Nos. 1 through 14 shown below.

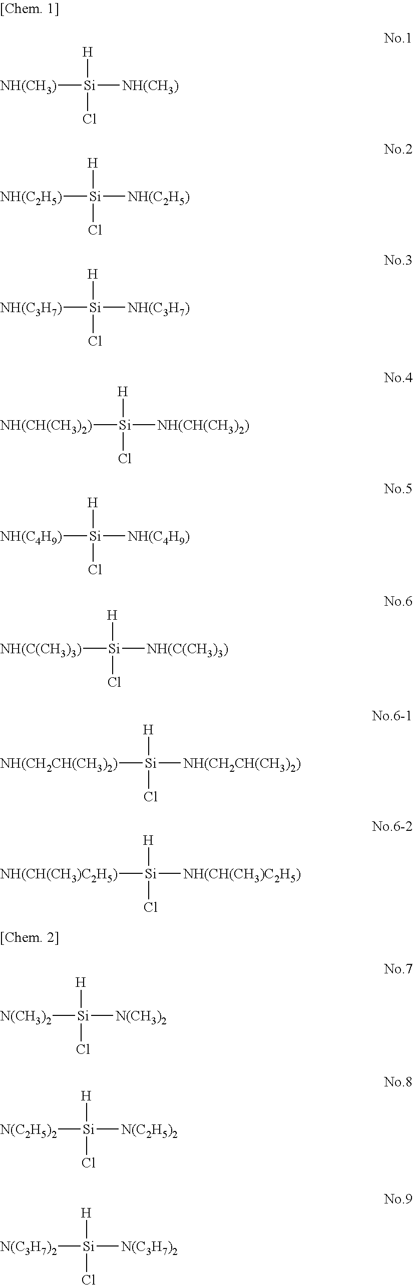

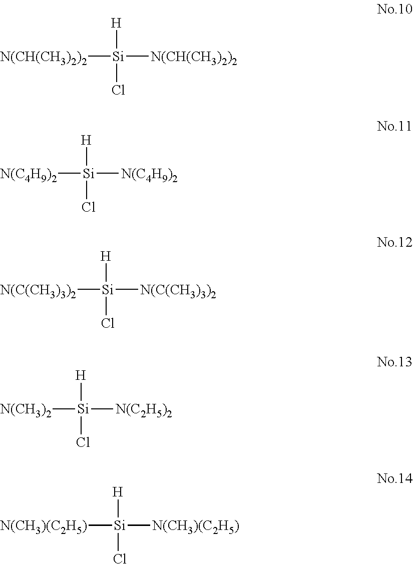

Of the silicon-containing compounds, preferred are those in which R¹, R², R³, and R⁴ are each alkyl with fewer carbon atoms (particularly alkyl with 2 or less carbon atoms) because those having a smaller molecular weight are more volatile.

The organic silicon-containing compound represented by general formula: HSiCl(NR¹R²)(NR³R⁴) is synthesized using conventionally known reactions. For example, it is synthesized by the reaction between trichlorosilane and a primary or secondary amine(s) corresponding to the amino groups possessed by a desired organic silicon-containing compound (i.e., —NR¹R² and —NR³R⁴). The reaction may be carried out in a solvent, such as an ether solvent (e.g., methyl tert-butyl ether, diethyl ether, 1,2-dimethoxyethane, 1,2-diethoxyethane, or diglyme), THF, tetrahydropyran, or an aliphatic hydrocarbon solvent (e.g., n-pentane, n-hexane, or n-heptane). The primary or secondary amine(s) is/are preferably used in a reaction ratio of 1.8 to 3.0 mol per mole of trichlorosilane. The reaction is preferably performed at −70° to 60° C. for a period of 12 hours or shorter.

The chemical vapor deposition material of the invention contains the above described organic silicon-containing compound. That is, the chemical vapor deposition material is the organic silicon-containing compound per se or a composition containing the organic silicon-containing compound. The form of the chemical vapor deposition material of the invention is chosen as appropriate to the procedure employed to carry out the chemical vapor deposition, for example, the source delivery system.

The source delivery system (raw material feed step) is exemplified by a vapor delivery system in which a chemical vapor deposition material is vaporized by heating and/or pressure reduction in a container and introduced into a deposition chamber, if desired, together with a carrier gas, e.g., argon, nitrogen or helium, and a liquid delivery system in which a chemical vapor deposition material is delivered in the form of a liquid or a solution to a vaporizer, where it is vaporized by heating and/or pressure reduction and then led to a deposition chamber. When applied to the vapor delivery system, the organic silicon-containing compound represented by general formula: HSiCl(NR¹R²)(NR³R⁴) per se is the chemical vapor deposition material. In the case of the liquid delivery system, the organic silicon-containing compound represented by general formula: HSiCl(NR¹R²)(NR³R⁴)per se or a solution of the compound in an organic solvent is the chemical vapor deposition material.

In a multi-component chemical vapor phase deposition process used to fabricate a multi-component thin film, the source delivery systems include a system in which a plurality of the materials are separately vaporized and delivered (hereinafter referred to as a single source system) and a system in which a plurality of the materials are previously mixed at a prescribed ratio, and the mixture is vaporized and delivered (hereinafter referred to as a multi-source system). In the case of the multi-source system, the material for chemical vapor deposition may be a mixture of the organic silicon-containing compounds of formula: HSiCl(NR¹R²)(NR³R⁴), a solution of the mixture in an organic solvent, a mixture of the organic silicon-containing compound(s) of formula: HSiCl(NR¹R²)(NR³R⁴)and other precursor(s), or a mixed solution of the mixture in an organic solvent.

The organic solvent that can be used in the material for chemical vapor deposition is not particularly limited, and any widely known organic solvent may be used as long as it is inert to the organic silicon-containing compound and other precursors used in combination where needed. Examples of useful organic solvents include acetic esters, such as ethyl acetate, butyl acetate, and methoxyethyl acetate; ethers, such as tetrahydrofuran, tetrahydropyran, morpholine, ethylene glycol dimethyl ether, diethylene glycol dimethyl ether, triethylene glycol dimethyl ether, dibutyl ether, and dioxane; ketones, such as methyl butyl ketone, methyl isobutyl ketone, ethyl butyl ketone, dipropyl ketone, diisobutyl ketone, methyl amyl ketone, cyclohexanone, and methylcyclohexanone; hydrocarbons, such as hexane, cyclohexane, methylcyclohexane, dimethylcyclohexane, ethylcyclohexane, heptane, octane, toluene, and xylene; hydrocarbons having a cyano group, such as acetonitrile, 1-cyanopropane, 1-cyanobutane, 1-cyanohexane, cyanocyclohexane, cyanobenzene, 1,3-dicyanopropane, 1,4-dicyanobutane, 1,6-dicyanohexane, 1,4-dicyanocyclohexane, and 1,4-dicyanobenzene; pyridine, and lutidine. A solvent or a mixture of solvents to be used is selected according to, for example, solubility of the solute and the boiling temperature or ignition temperature in relation to the working temperature. In using these organic solvents, the total concentration of the precursor component(s) in the organic solvent is preferably 0.01 to 2.0 mol/l, still preferably 0.05 to 1.0 mol/l.

The other precursors (precursors containing an element other than silicon) include compounds formed between a metal element and at least one compound selected from the group consisting of organic coordinating compounds, such as alcohol compounds, glycol compounds, β-diketone compounds, cyclopentadiene compounds, and organic amine compounds. The metal species of the other precursors other than silicon include the Group 1 elements, such as lithium, sodium, potassium, rubidium, and cesium; the Group 2 elements, such as beryllium, magnesium, calcium, strontium, and barium; the Group 3 elements, such as scandium, yttrium, lanthanoid elements (i.e., lanthanum, cerium, praseodymium, neodymium, promethium, samarium, europium, gadolinium, terbium, dysprosium, holmium, erbium, thulium, ytterbium, and lutetium), and actinoid elements; the Group 4 elements, such as titanium, zirconium, and hafnium; the Group 5 elements, such as vanadium, niobium, and tantalum; the Group 6 elements, such as chromium, molybdenum, and tungsten; the Group 7 elements, such as manganese, technetium, and rhenium; the Group 8 elements, such as iron, ruthenium, and osmium; the Group 9 elements, such as cobalt, rhodium, and iridium; the Group 10 elements, such as nickel, palladium, and platinum; the Group 11 elements, such as copper, silver, and gold; the Group 12 elements, such as zinc, cadmium, and mercury; the Group 13 elements, such as aluminum, gallium, indium, and thallium; the Group 14 elements, such as germanium, tin, and lead; and the Group 15 elements, such as arsenic, antimony, and bismuth; and the Group 16 elements, such as polonium.

Examples of the alcohol compounds that can be used as an organic ligand include alkyl alcohols, such as methanol, ethanol, propanol, isopropanol, butanol, 2-butanol, isobutanol, tert-butanol, amyl alcohol, isoamyl alcohol, and tert-amyl alcohol; ether alcohols, such as 2-methoxyethanol, 2-ethoxyethanol, 2-butoxyethanol, 2-(2-methoxyethoxy)ethanol, 2-methoxy-1-methylethanol, 2-methoxy-1,1-dimethylethanol, 2-isopropoxy-1,1-dimethylethanol, 2-butoxy-1,1-dimethylethanol, 2-(2-methoxyethoxy)-1,1-dimethylethanol, 2-propoxy-1,1-diethylethanol, 2-sec-butoxy-1,1-diethylethanol, and 3-methoxy-1,1-dimethylpropanol; and dialkylamino alcohols, such as N,N-dimethylaminoethanol, 1,1-dimethylamino-2-propanol, and 1,1-dimethylamino-2-methyl-2-propanol.

Examples of the glycol compounds that can be used as an organic ligand include 1,2-ethanediol, 1,2-propanediol, 1,3-propanediol, 2,4-hexanediol, 2,2-dimethyl-1,3-propanediol, 2,2-diethyl-1,3-propanediol, 1,3-butanediol, 2,4-butanediol, 2,2-diethyl-1,3-butanediol, 2-ethyl-2-butyl-1,3-propanediol, 2,4-pentanediol, 2-methyl-1,3-propanediol, 2-methyl-2,4-pentanediol, 2,4-hexanediol, and 2,4-dimethyl-2,4-pentanediol.

Examples of the β-diketone compounds that can be used as an organic ligand include alkyl-substituted β-ketones, such as acetylacetone, hexane-2,4-dione, 5-methylhexane-2,4-dione, heptane-2,4-dione, 2-methylheptane-3,5-dione, 5-methylheptane-2,4-dione, 6-methylheptane-2,4-dione, 2,2-dimethylheptane-3,5-dione, 2,6-dimethylheptane-3,5-dione, 2,2,6-trimethylheptane-3,5-dione, 2,2,6,6-tetramethylheptane-3,5-dione, octane-2,4-dione, 2,2,6-trimethyloctane-3,5-dione, 2,6-dimethyloctane-3,5-dione, 2,2-dimethyl-6-ethyloctane-3,5-dione, 2,2,6,6-tetramethyloctane-3,5-dione, 2,9-dimethylnonane-4,6-dione, 2,2,6,6-tetramethyl-3,5-nonanedione, 2-methyl-6-ethyldecane-3,5-dione, and 2,2-dimethyl-6-ethyldecane-3,5-dione; fluoroalkyl-substituted β-diketones, such as 1,1,1-trifluoropentane-2,4-dione, 1,1,1-trifluoro-5,5-dimethylhexane-2,4-dione, 1,1,1,5,5,5-hexafluoropentane-2,4-dione, and 1,3-diperfluorohexylpropane-1,3-dione; and ether-substituted β-diketones, such as 1,1,5,5-tetramethyl-1-methoxyhexane-2,4-dione, 2,2,6,6-tetramethyl-1-methoxyheptane-3,5-dione, and 2,2,6,6-tetramethyl-1-(2-methoxyethoxy)heptane-3,5-dione.

Examples of the cyclopentadiene compounds that can be used as an organic ligand include cyclopentadiene, methylcyclopentadiene, ethylcyclopentadiene, propylcyclopentadiene, isopropylcyclopentadiene, butylcyclopentadiene, sec-butylcyclopentadiene, isobutylcyclopentadiene, tert-butylcyclopentadiene, dimethylcyclopentadiene, and tetramethylcyclopentadiene.

Examples of the organic amine compounds that can be used as an organic ligand include methylamine, ethylamine, propylamine, isopropylamine, butylamine, sec-butylamine, tert-butylamine, isobutylamine, dimethylamine, diethylamine, dipropylamine, diisopropylamine, ethylmethylamine, propylmethylamine, isopropylmethylamine, and bis(trimethylsilyl)amine.

When, for example, a thin film of a silicon component/zirconium double nitride is deposited by the process of the invention, a preferred zirconium precursor is a tetrakis(dialkylamino)zirconium, particularly tetrakis(dimethylamino)zirconium, tetrakis(diethylamino)zirconium, or tetrakis(ethylmethylamino)zirconium. When a thin film of a silicon component/hafnium double nitride is deposited by the process of the invention, a preferred hafnium precursor is a tetrakis(dialkylamino)hafnium, particularly tetrakis(dimethylamino)hafnium, tetrakis(diethylamino)hafnium, or tetrakis(ethylmethylamino)hafnium.

If desired, the material for chemical vapor deposition of the invention may contain a nucleophilic reagent to stabilize the organic silicon-containing compound and any other precursor. Examples of the nucleophilic reagent include ethylene glycol ethers, such as glyme, diglyme, triglyme, and tetraglyme; crown ethers, such as 18-crown-6, dicyclohexyl-18-crown-6, 24-crown-8, dicyclohexyl-24-crown-8, and dibenzo-24-crown-8; polyamines, such as ethylenediamine, N,N′-tetramethylethylenediamine, diethylenetriamine, triethylenetetramine, tetraethylenepentamine, pentaethylenehexamine, 1,1,4,7,7-pentamethyldiethylene-triamine, 1,1,4,7,10,10-hexamethyl-triethylenetetramine, and triethoxy-triethyleneamine; cyclic polyamines, such as cyclam and cyclen; heterocyclic compounds, such as pyridine, pyrrolidine, piperidine, morpholine, N-methylpyrrolidine, N-methylpiperidine, N-methylmorpholine, tetrahydrofuran, tetrahydropyran, 1,4-dioxane, oxazole, thiazole, and oxathiolane; β-keto esters, such as methyl acetoacetate, ethyl acetoacetate, and 2-methoxyethyl acetoacetate; and β-diketones, such as acetylacetone, 2,4-hexanedione, 2,4-heptanedione, 3,5-heptanedione, and dipivaloylmethane. The amount of the nucleophilic reagent to be used as a stabilizer is preferably 0.05 to 10 mol, more preferably 0.1 to 5 mol, per mole of the precursor(s).

The chemical vapor deposition material of the invention should have minimized contents of impurities other than the constituent components, including impurity metal elements, impurity halogens (e.g., impurity chlorine), and impurity organic matter. The impurity metal element content is preferably 100 ppb or less, more preferably 10 ppb or less, for every element, and a total impurity metal content is preferably 1 ppm or less, more preferably 100 ppb or less. In particular, in the fabrication of a thin film for use as a gate insulator film, a gate film, or a barrier film of LSI devices, it is required to minimize the contents of alkali metal elements, alkaline earth metal elements, and congeneric elements (Ti, Zr, or Hf) that are influential on the electrical characteristics of the resulting thin film. The impurity halogen content is preferably 100 ppm or less, more preferably 10 ppm or less, even more preferably 1 ppm or less. The total impurity organic matter content is preferably 500 ppm or less, more preferably 50 ppm or less, even more preferably 10 ppm or less. A water content causes particle generation in the chemical vapor deposition material or during thin film formation. Therefore, it is advisable to previously remove the water content from the precursor, the organic solvent, and the nucleophilic reagent as much as possible before use. The water content of each of the precursor, organic solvent, and nucleophilic reagent is preferably 10 ppm or less, more preferably 1 ppm or less.

In order to reduce or prevent contamination of a thin film with particles, it is desirable for the chemical vapor deposition material of the invention to have minimized particles. Specifically, it is desirable for the material to have not more than 100 particles greater than 0.3 μm, more desirably not more than 1000 particles greater than 0.2 μm, even more desirably not more than 100 particles greater than 0.2 μm, per ml of its liquid phase as measured with a light scattering particle sensor for detecting particles in a liquid phase.

The process of forming a silicon-containing thin film according to the present invention is characterized by using the above described chemical vapor deposition material of the invention. The process is not particularly restricted by the material delivery system, the mode of deposition, the film formation conditions, the film formation equipment, and the like. Any conditions and methods commonly known in the art are made use of. The film formation process of the invention is particularly suitable to form a silicon nitride thin film at low temperatures.

The thin film formation according to the invention will be described in more detail taking, for instance, the formation of a silicon nitride thin film.

The formation of a silicon nitride thin film starts with the above-mentioned material feed step, in which the organic silicon-containing compound related to the invention, which is contained as a precursor in the chemical vapor deposition material of the invention, is delivered to a deposition chamber. A silicon-containing thin film is deposited on a substrate using the precursor delivered to the deposition chamber (silicon-containing thin film deposition step), in which step the substrate may be heated, or the deposition chamber may be heated to apply heat to the substrate. The silicon-containing thin film deposited in this step is a precursor thin film or a thin film resulting from the decomposition and/or reaction of the precursor and therefore has a different composition from that of a pure silicon-containing thin film. The heating temperature of the substrate or the deposition chamber is preferably 50° to 500° C., more preferably 100° to 500° C. If the temperature is lower than 50° C., the finally obtained silicon nitride thin film tends to have an increased residual carbon content. Even if the temperature exceeds 500° C., the finally resulting thin film shows no further improvement in quality.

Subsequently, unreacted precursor vapor and by-produced gas are removed from the deposition chamber (exhaust step). While ideally unreacted precursor vapor and by-produced gas are completely removed from the deposition chamber, complete exhaustion is not always required. Exhaustion is achieved by, for example, purging the chamber with an inert gas, such as helium or argon and/or reducing the pressure in the chamber. Pressure reduction is preferably performed to a pressure of 20000 to 10 Pa.

Into the deposition chamber is then introduced NH₃ gas or N₂ gas to convert the silicon-containing thin film deposited in the preceding silicon-containing thin film deposition step to a silicon nitride thin film by the action of the NH₃ or N₂ gas and the heat (silicon nitride thin film formation step). The temperature of the heat applied to the silicon-containing thin film in this step is preferably 100° to 500° C. If it is lower than 100° C., the resulting silicon nitride thin film tends to have an increased residual carbon content. Even if the temperature exceeds 500° C., no further improvement in silicon nitride thin film quality is obtained. The heat application to the silicon-containing thin film may be effected by heating the substrate or the whole deposition chamber, preferably to a temperature of 100° to 500° C.

The thin film formation process of the invention comprises at least one cycle including the material feed step, silicon-containing thin film deposition step, exhaust step, and silicon nitride thin film formation step. This cycle may be repeated until a thin film of a desired thickness is built up. When the cycle is repeated, it is preferred that every cycle be followed by removing the unreacted precursor vapor, NH₃ gas or N₂ gas, and by-produced gas from the deposition chamber in the same manner as in the exhaust step prior to the next cycle.

Energy, such as plasma, light, or voltage, may be applied in the thin film formation process of the invention. The stage of applying the energy is not particularly limited and may be, for example, at the time of feeding precursor vapor in the material feed step, at the time of heating in the silicon-containing thin film deposition step or the silicon nitride thin film formation step, at the time of evacuating the system in the exhaust step, at the time of introducing NH₃ gas or N₂ gas in the silicon nitride thin film formation step, or between any two of the steps.

The pressure during depositing a silicon-containing thin film in the silicon-containing thin film deposition step and the reaction pressure in the silicon nitride thin film formation step in the thin film formation process of the invention are each preferably from atmospheric pressure to 10 Pa. When plasma is used, these pressures are each preferably 2000 to 10 Pa.

In the film formation process of the invention, the resulting thin film may be subjected to annealing in an inert atmosphere or an NH₃ or N₂ gas atmosphere to obtain improved film qualities. Where step coverage is required, the process may include the step of reflowing the thin film. In this case, the temperature is preferably from 400° to 1200° C., particularly preferably 500° to 800° C.

In the case when a thin film containing silicon and other elements is to be formed, a chemical vapor deposition material containing a precursor of a metal element other than silicon may be used in the film formation process of the invention separately from the chemical vapor deposition material of the invention containing the organic silicon-containing compound represented by HSiCl(NR¹R²)(NR³R⁴) (wherein R¹ and R³ each represent C1-C4 alkyl or hydrogen; and R² and R⁴ each represent C1-C4 alkyl). In this case, the chemical vapor deposition materials are each independently vaporized and delivered. The chemical vapor deposition material containing a precursor of a metal element other than silicon may be prepared in the same manner as for the chemical vapor deposition material containing the organic silicon-containing compound of the invention. The precursor of a metal element other than silicon may be incorporated into the chemical vapor deposition material of the invention together with the organic silicon-containing compound and vaporized and delivered all together. In either delivery system, the amount of the precursor of a metal element other than silicon is decided as appropriate to the desired thin film composition.

Examples of the compositions of the thin film containing silicon and other element(s) include silicon-titanium double oxide, silicon-zirconium double oxide, silicon-hafnium double oxide, silicon-bismuth-titanium complex oxide, silicon-hafnium-aluminum complex oxide, silicon-hafnium-rare earth element complex oxides, and silicon-hafnium double oxynitride (HfSiON). Applications of these thin films include electronic elements of electronic components, such as high dielectric constant capacitor films, gate insulators, gate films, electrode films, and barrier films, and optical glass elements, such as optical fibers, optical waveguides, optical amplifiers, and optical switches.

### EXAMPLES

The present invention will now be illustrated in greater detail with reference to Examples and Comparative Examples, but it should be understood that the invention is not construed as being limited thereto. Unless otherwise noted, all the parts and percents are by mass.

### Example 1

### Preparation of HSiCl(N(CH₃)(C₂H₅))₂ (Compound No. 14)

A reaction flask was charged with 41.0 g of HSiCl₃ and 365 ml of methyl tert-butyl ether (hereinafter “MTBE”), and the mixture was cooled to −30° C. To the mixture was added 79.0 g of NH(CH₃)(C₂H₅) in a dropwise manner such that the reaction system temperature might not exceed −20° C. After completion of the dropwise addition, the reaction mixture was stirred at room temperature for 3 hours, filtered under pressure, washed with 71 ml of MTBE. MTBE was removed by evaporation at 50° C. under reduced pressure, and the residue was distilled under reduced pressure. From the fraction at 1200 Pa and a distillation temperature of 53° C. was obtained HSiCl(N(CH₃)(C₂H₅))₂ as a desired product in a yield of 70%. The resulting compound was identified by ¹H-NMR analysis.

¹H-NMR (solvent: deuterated benzene) (chemical shift:multiplicity:proton ratio): (5.126:s:1) (2.773:quartet:4) (2.365:s:6) (0.916:t:6)

### Example 2

### Preparation of HSiCl(N(C₂H₅)₂)₂ (Compound No. 8)

A reaction flask was charged with 75.0 g of HSiCl₃ and 360 ml of THF, followed by cooling to 0° C. To the mixture was added a mixed solution of 165.33 g of NH(C₂H₅)₂ and 70 ml of THF in a dropwise manner such that the reaction system temperature might not exceed 5° C. After completion of the dropwise addition, the reaction mixture was stirred at room temperature for 3 hours, heated at 45° C., and further stirred for 9 hours. The reaction mixture was filtered under pressure, washed with THF, and evaporated at 50° C. under reduced pressure to remove THF, and the residue was distilled under reduced pressure. From the fraction at 250 Pa and a distillation temperature of 44° C. was obtained HSiCl(N(C₂H₅)₂)₂ as a desired product in a yield of 62%. The resulting compound was identified by ¹H-NMR analysis.

¹H-NMR (solvent: deuterated benzene) (chemical shift:multiplicity:proton ratio): (5.121:s:1) (2.835:quartet:8) (0.942:t:12)

### Example 3

### Preparation of HSiCl(HNC(CH₃)₃)₂ (Compound No. 6)

A reaction flask was charged with 75.0 g of HSiCl₃ and 190 ml of THF, followed by cooling to 0° C. To the mixture was added a mixed solution of 163.77 g of NH₂(C(CH₃)₃) and 77 ml of THF in a dropwise manner such that the reaction system temperature might not exceed 5° C. After completion of the dropwise addition, the reaction mixture was stirred at room temperature for 3 hours, heated to 55° C., and further stirred for 4 hours. The reaction mixture was filtered under pressure, washed with THF, and evaporated at 50° C. under reduced pressure to remove THF, and the residue was distilled under reduced pressure. From the fraction at 1470 Pa and a distillation temperature of 74° C. was obtained HSiCl(HNC(CH₃)₃)₂ as a desired product in a yield of 62%. The resulting compound was identified by ¹H-NMR analysis.

¹H-NMR (solvent: deuterated benzene) (chemical shift:multiplicity:proton ratio): (5.440:s:1) (1.100:s:20)

### Evaluation Example 1

### Evaluation of Volatility

Each of compound Nos. 14, 8, and 6 obtained in Examples 1 to 3 and comparative compound Nos. 1 to 5 shown in Table 1 below was analyzed by TG-DTA (argon flow rate: 100 ml/min; rate of temperature rise: 10° C./min). The 50% mass loss temperature and the first mass loss end temperature and percent residue (by mass) as determined in the TG-DTA analysis are shown in Table 2.

TABLE 1

| Organic Si-containing Compound | Structural Formula |
|---|---|
| Compound No. 14 | HSiCl(N(CH₃)(C₂H₅))₂ |
| Compound No. 8 | HSiCl(N(C₂H₅)₂)₂ |
| Compound No. 6 | HSiCl(HNC(CH₃)₃)₂ |
| Comparative compound No. 1 | HSi(N(C₂H₅)₂)₃ |
| Comparative compound No. 2 | HSi(HNC(CH₃)₃)₃ |
| Comparative compound No. 3 | Si(N(C₂H₅)₂)₄ |
| Comparative compound No. 4 | SiCl(N(C₂H₅)₂)₃ |
| Comparative compound No. 5 | SiCl₂(N(C₂H₅)₂)₂ |

TABLE 2

| Organic Si-containing | 50% Mass Loss | Mass Loss End Temp. |
|---|---|---|
| Compound | Temp. (° C.) | (° C.)/Residue (%) |
| Compound No. 14 | 100 | 130/0 |
| Compound No. 8 | 127 | 161/0 |
| Compound No. 6 | 127 | 161/0 |
| Comparative compound No. 1 | 160 | 194/0.07 |
| Comparative compound No. 2 | 144 | 181/0 |
| Comparative compound No. 3 | 170 | 195/0.28 |
| Comparative compound No. 4 | 179 | 210/0.15 |
| Comparative compound No. 5 | 149 | 186/0.06 |

It is seen from Table 2 that compound Nos. 14, 8, and 6, i.e., the organic silicon-containing compounds represented by the specific general formula that are contained in the chemical vapor deposition material of the invention are volatile at lower temperatures than comparative compound Nos. 1 through 5. Therefore, the chemical vapor deposition materials of the invention containing the organic silicon-containing compound are proved useful as a material of chemical vapor deposition processes involving volatilization of the material.

### Evaluation Example 2

### Evaluation of Reactivity

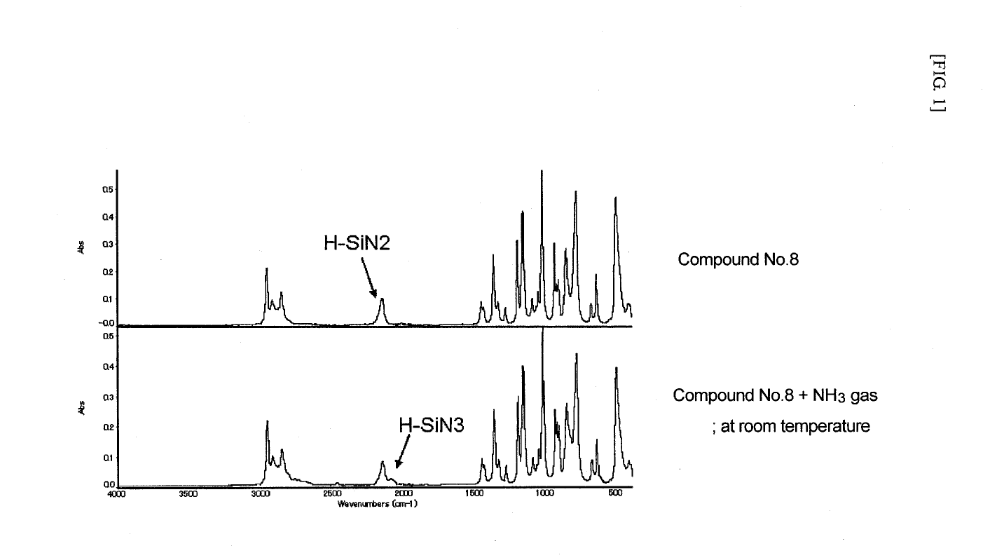

One part of compound No. 8 or comparative compound No. 1 was put into a flask having an argon atmosphere, and 30 parts of NH₃ gas was introduced therein at room temperature and 200° C. The liquid phase in the flask was analyzed by FT-IR, and the resulting spectrum was compared with that obtained before the NH₃ gas introduction. The results are shown in FIGS. 1 to 3.

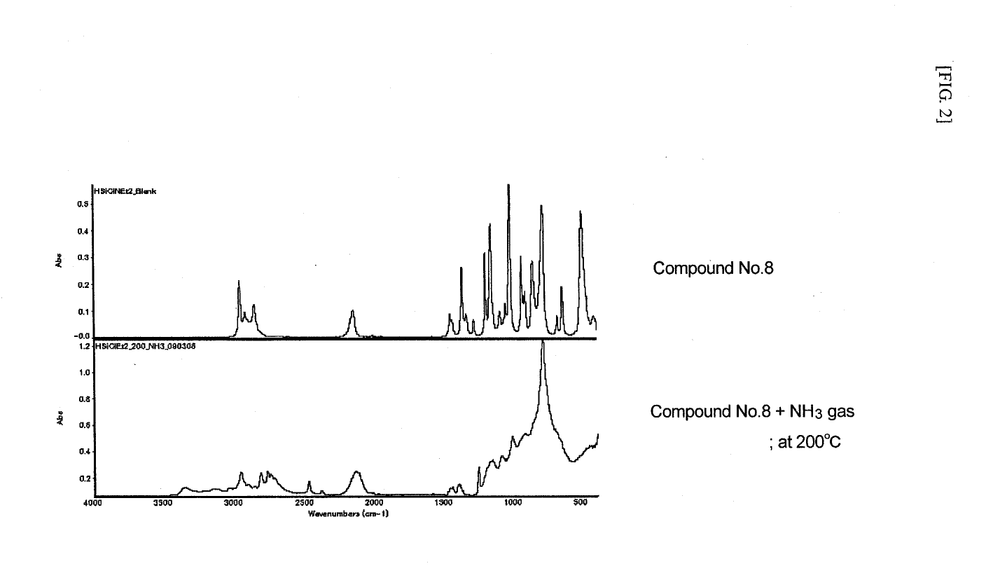

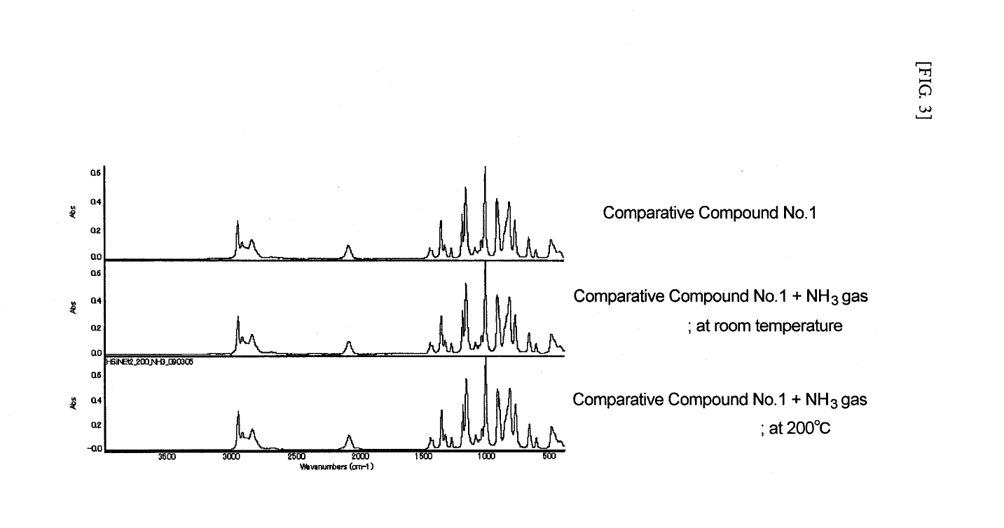

FIGS. 1 and 2 show that the peak of H—SiN₃ that is not observed before NH₃ gas introduction appears after the NH₃ gas introduction, demonstrating that the Cl bonded to Si of compound No. 8 has been replaced with N. It is believed from this that compound No. 8 reacts with NH₃ gas. In contrast, FIG. 3 shows no change of peaks, indicating that comparative compound No. 1 does not react with NH₃ gas. All these results demonstrate that the organic silicon-containing compound related to the invention exhibits good reactivity with NH₃ gas by virtue of its Si—Cl bond.

### Evaluation Example 3

### Evaluation of Adsorption to Substrate

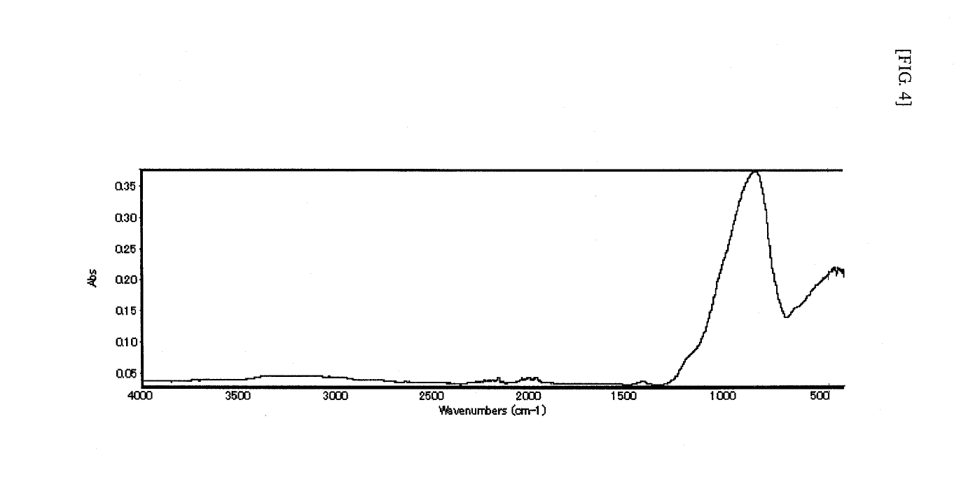

One part of compound No. 8 was put into a flask having an argon atmosphere, and 30 parts of NH₃ gas was introduced therein at room temperature. The liquid phase in the flask was dropped on a silicon wafer and heated at 700° C. for 10 minutes in an argon atmosphere. The thus treated silicon wafer was analyzed by FT-IR. The results are shown in FIG. 4.

The spectrum of FIG. 4 shows disappearance of the peaks of the alkyl groups at around 1200 cm⁻¹ and of the amino groups (C—N) around 1000 cm⁻¹ and appearance of the peak of Si—N around 800 to 900 cm⁻¹, indicating the formation of Si—Nₓ. The same evaluation was made on comparative compound No. 1, but the peak was not observed. These results prove compound No. 8 capable of adsorption onto an Si wafer and reaction with ammonia to give a silicon nitride film. It was also confirmed that comparative compound No. 1 is incapable of forming a film on an Si wafer on account of its weak adsorption onto the Si wafer.

### Example 4

### Fabrication of Silicon Nitride Thin Film

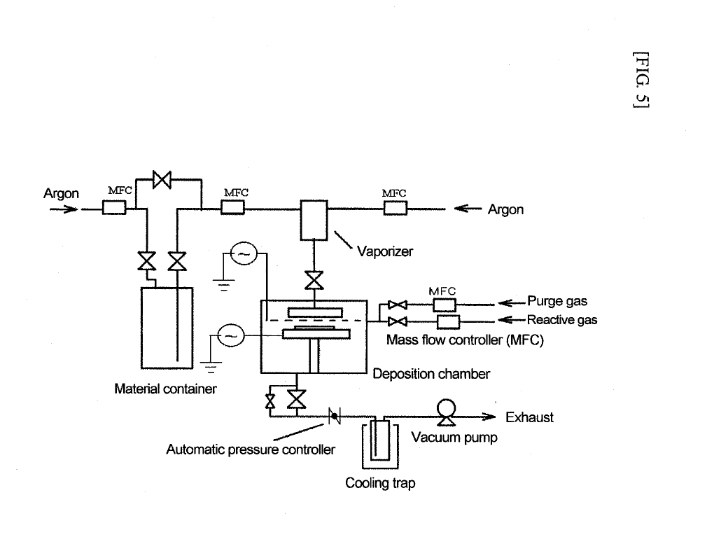

A silicon nitride thin film was fabricated on a silicon wafer by ALD using the equipment illustrated in FIG. 5 and compound No. 8 obtained in Example 1 as a chemical vapor deposition material under the following conditions in accordance with the following procedure. The resulting film was analyzed by X-ray fluorometry to determine the film thickness and composition. It was found as a result that the film thickness was 20 nm, the film composition was silicon nitride, and the carbon content was 0.5 atom %.

### ALD Conditions:

Reaction temperature (substrate temperature): 300° C.

Reactive gas: NH₃

High-frequency power: 500 W

### Procedure:

Forty cycles each comprising steps (1) to (4) were conducted.
(1) A chemical vapor deposition material vaporized in the vaporizer at 90° C. and 1500 Pa was delivered into the deposition chamber and allowed to deposit for 1 second under a system pressure of 200 Pa.
(2) The chamber was purged with argon for 3 seconds to remove the unreacted material.
(3) The reactive gas was introduced into the chamber and allowed to react for 1 second under a system pressure of 200 Pa.
(4) The chamber was purged with argon for 2 seconds to remove the unreacted material.

### Comparative Example 1

A silicon nitride thin film was fabricated on a silicon wafer by ALD using comparative compound No. 1 as a chemical vapor deposition material under the same conditions and procedure as in Example 4. The resulting film was analyzed by X-ray fluorometry to determine the film thickness and composition. It was found as a result that the film thickness was 3 nm, the film composition was silicon nitride, and the carbon content was 4.0 at %.

Comparison between Example 4 and Comparative Example 1 reveals that the use of the chemical vapor deposition material of the invention containing the specific organic silicon-containing compound allows for low-temperature formation of a thin film having good qualities with a low carbon content.

1. A material for chemical vapor deposition comprising an organic silicon-containing compound represented by formula:
HSiCl(NR¹R²)(NR³R⁴)
wherein R¹ and R³ each represent an alkyl group having 1 to 4 carbon atoms or hydrogen; and R² and R⁴ each represent an alkyl group having 1 to 4 carbon atoms.

2. The material for chemical vapor deposition according to claim 1, which is for the formation of a silicon nitride thin film on a substrate by chemical vapor deposition.

3. A process for forming a silicon-containing thin film by chemical vapor deposition using the material for chemical vapor deposition according to claim 1.

4. A process for forming a silicon nitride thin film by chemical vapor deposition using the material for chemical vapor deposition according to claim 2.
